(19) United States
(12) Patent Application Publication
(10) Pub. No.: US 2011/0253530 A1
(43) Pub. Date: Oct. 20, 2011

(54) SUBSTRATE HOLDING DEVICE AND SPUTTERING APPARATUS HAVING SAME

(75) Inventor: CHIA-YING WU, Tu-Cheng (TW)

(73) Assignee: HON HAI PRECISION INDUSTRY CO., LTD., Tu-Cheng (TW)

(21) Appl. No.: 12/853,305

(22) Filed: Aug. 10, 2010

(30) Foreign Application Priority Data
Apr. 14, 2010 (TW) 99111523

(51) Int. Cl. C23C 14/50; C23C 14/34

(52) U.S. Cl. 204/298.15

(57) ABSTRACT

A holding device includes a spindle, a number of aligned adapting members and a number of holders. The adapting members are mounted on the spindle. Each holder is movably coupled with a corresponding adapting member such that the distance between each holder and the spindle is adjustable.

### BACKGROUND

1. Technical Field

The present disclosure relates to sputtering technology, and particularly, to a substrate holding device and a related sputtering apparatus.

2. Description of Related Art

Sputtering is a physical vapor deposition process where atoms in a solid target are ejected into the gas phase and are deposited on workpieces facing the target. The workpieces are held by holders of a conventional substrate holding apparatus during a sputtering process.

Distances between each holder and the target is one of the most important factors for deposition quality. For instance, if the distance is too far, the film deposited on the workpiece will be thinner than that required. Unfortunately, the holder is unmovable relative to the target. As a result, the distance between each holder of the conventional holding apparatus and the target cannot be adjusted. Therefore, it is desired to provide a holding device capable of adjusting the distance between each holder and the target and a sputtering apparatus to improve deposition quality.

### BRIEF DESCRIPTION OF THE DRAWINGS

Many aspects of the present substrate holding device and sputtering apparatus can be better understood with reference to the following drawings. The components in the drawings are not necessarily drawn to scale, the emphasis instead being placed upon clearly illustrating the principles of the present substrate holding device and sputtering apparatus. Moreover, in the drawings, like reference numerals designate corresponding parts throughout the several views.

FIG. 1 is an isometric and top view of a substrate holding device in accordance with a first embodiment.

FIG. 2 is an isometric and cross-sectional view of the substrate holding device of FIG. 1, taken along lines II-II.

FIG. 3 is an isometric and top view of a substrate holding device in accordance with a second embodiment.

FIG. 4 is an isometric and cross-sectional view of the substrate holding device of FIG. 3, taken along lines IV-IV.

FIG. 5 is an isometric and cross-sectional view of an exemplary sputtering apparatus having the substrate holding device of FIG. 1.

### DETAILED DESCRIPTION

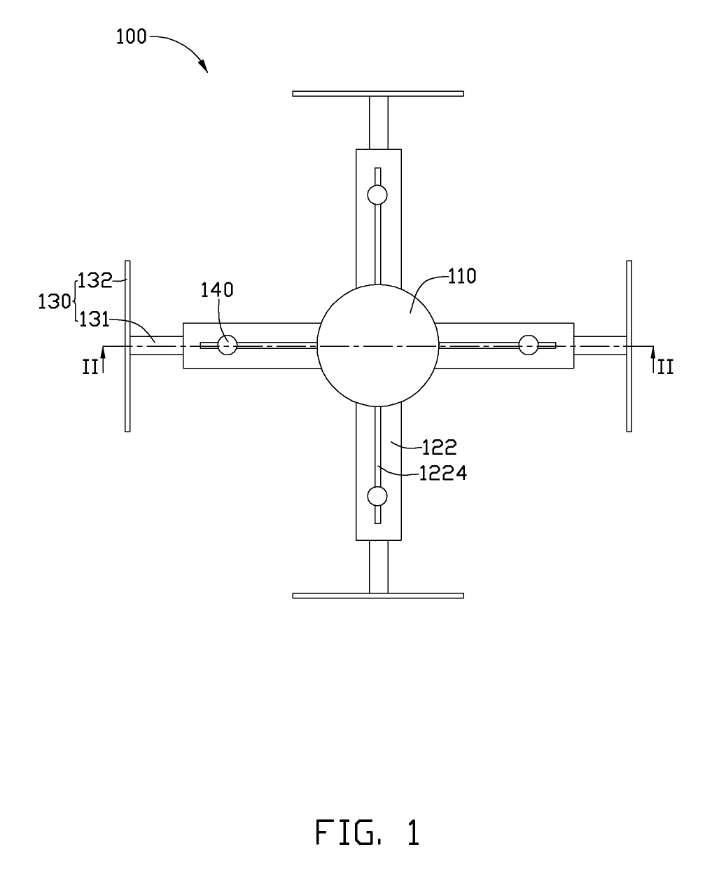

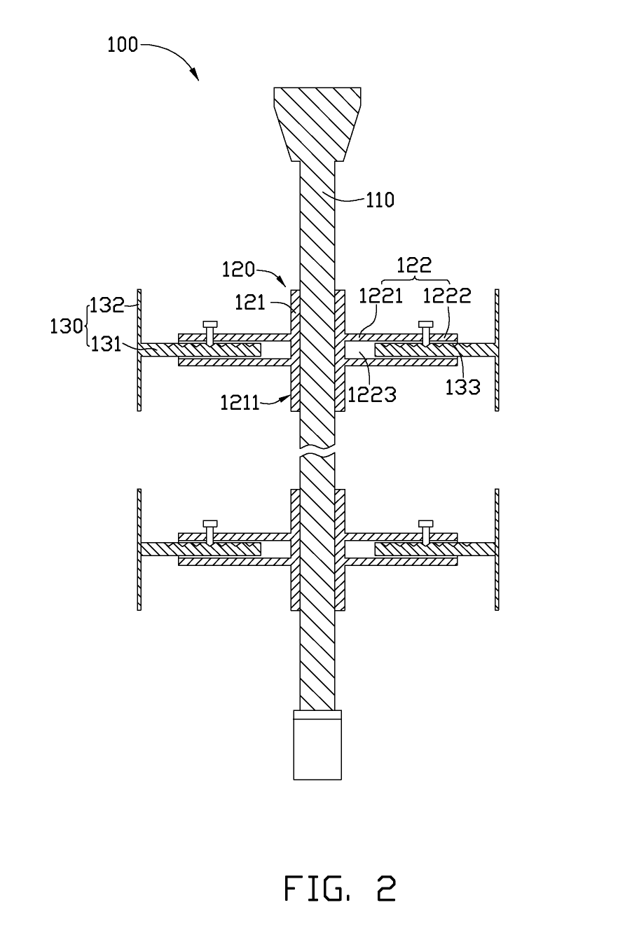

Referring to FIGS. 1 and 2, a substrate holding device 100 according to a first embodiment includes a spindle 110, a plurality of adapting members 120, a plurality of holders 130, and a plurality of positioning members 140.

Referring to FIG. 2, each adapting member 120 includes a sleeve 121 and four hollow cylinders 122. The spindle 110 penetrates each sleeve 121. The sleeve 121 can be fixed at a predetermined position on the spindle 110 with typical fasteners, for instance, bolts. The sleeve 121 is movable along the spindle 110 by withdrawing the fasteners and can be fixed at another predetermined position of the spindle 110 using the fasteners. That means, the distance between two neighboring adapting members 120 is adjustable. The sleeve 121 has an outer circumferential surface 1211.

Referring to FIG. 2, each hollow cylinder 122 has a first end 1221 and a second end 1222 opposite to the first end 1221. Referring to FIGS. 1 and 2, the first end 1221 vertically extends from the outer circumferential surface 1211 outwardly. The four first ends 1221 are radially arranged on the circumferential surface 1211. Each hollow cylinder 122 defines a inner hole 1223 and a slot 1224 communicating with the inner hole 1223. The slot 1224 starts from an end surface of the hollow cylinder 122, which is adjacent to the first end 1221, then extends longitudinally along the hollow cylinder 122, and expires at a predetermined position adjacent to the second end 1222.

The holder 130 includes a rod portion 131 and a plate portion 132. The plate portion 132 intersects with the rod portion 131 and forms a T-shaped configuration with the rod portion 131. The plate portion 132 is used for holding workpieces. A plurality of positioning recesses is longitudinally defined in the rod portion 131. The rod portion 131 is movably inserted in the inner hole 1223 of the hollow cylinder 122. That is, the plate portion 132 is telescopically coupled to the spindle 110, with the distance between the plate portion 132 and the spindle 110 being adjustable.

Referring to FIGS. 1 and 2, each positioning member 140 detachably passes through a corresponding slot 1224 and an end thereof fittingly accommodates in a corresponding positioning recess 133. As such, the positioning member 140 positions the rod portion 131 of the holder 130 at a predetermined position relative to the hollow cylinder 122. In the present embodiment, the positioning members 140 are bolts.

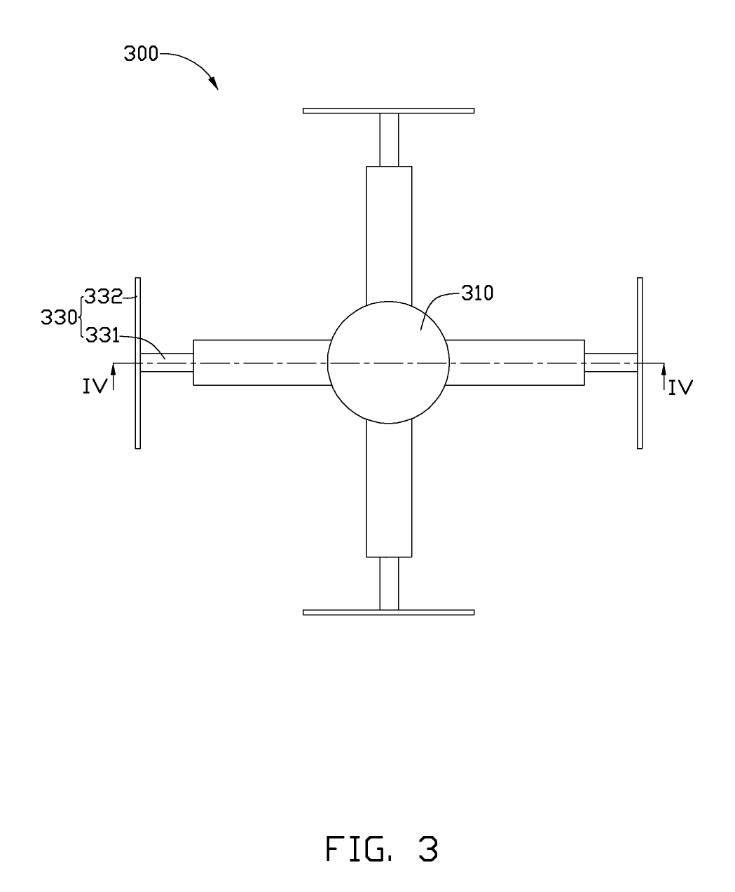

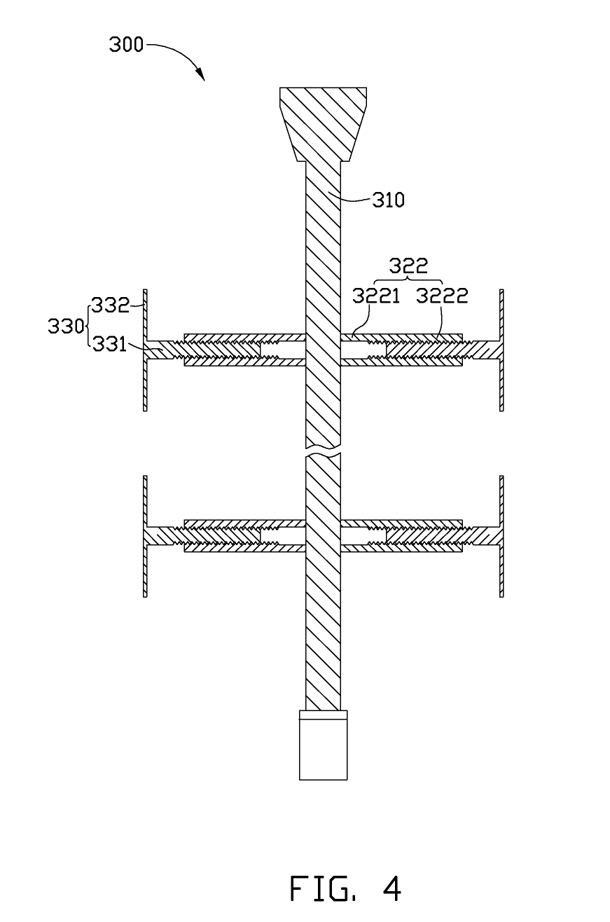

Referring to FIGS. 3 and 4, another substrate holding device 300 in accordance to a second embodiment has similar configuration with that of the substrate holding device 100. The substrate holding device 300 includes a spindle 310, a plurality of adapting members 322, and a plurality of holders 330.

Each of the adapting members 322 are comprised of four hollow cylinders. The four hollow cylinders respectively extend from the spindle 310 outwardly. Each hollow cylinder includes a first end 3221 and a second end 3222. The first end 3221 radially extends from spindle 310. The holder 330 includes a rod portion 331 threadedly engaged with the cylinder 322 and a plate portion 332 for holding the workpieces.

Referring to FIGS. 1, 2 and 5, a sputtering apparatus 200 includes a vacuum chamber 210. In addition, the sputtering apparatus 200 includes two targets 220, two holding devices 100, and a rotatable carrier 230 accommodated in the vacuum chamber 210. Two targets 220 are fixed on sidewall of the vacuum chamber 210 in a manner that the central axis of each target 220 is parallel to the central axis of the vacuum chamber 210. The rotatable carrier 230 is rotatable around the central axis of itself. The plate portions 132 of each of the holding devices 100 face a corresponding target 220. The spindle 110 is vertically fixed on the rotatable carrier 230. As such, each of the two holding devices 100 is capable of rotating around the central axis of the rotatable carrier 230. Additionally, the spindle 110 is capable of rotating around its central axis as well.

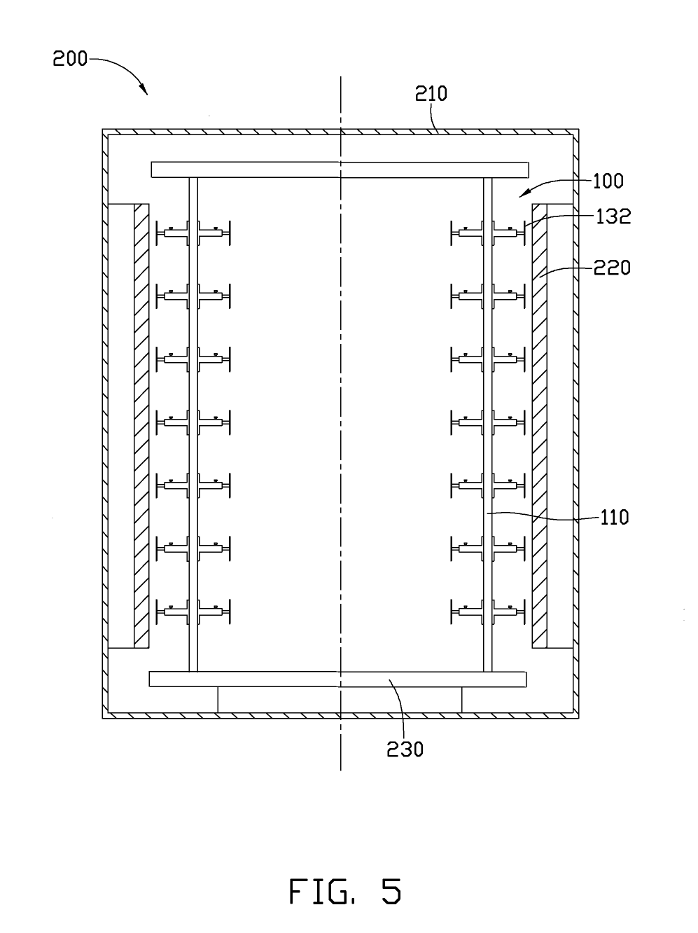

In actual use, during a sputtering process, referring to FIGS. 2 and 5, the positioning members 140 are withdrawn from the cylinder 122, the plate portion 131 is moved to a predetermined position in the cylinder 122, and then the positioning members 140 are used for positioning the plate portion 131 at the predetermined position. In this way, the distance between the holders 232 and the target 220 is adjustable for different workpieces.

It is understood that the above-described embodiments are intended to illustrate rather than limit the disclosure. Variations may be made to the embodiments and methods without departing from the spirit of the disclosure. Accordingly, it is appropriate that the appended claims be construed broadly and in a manner consistent with the scope of the disclosure.

What is claimed is:

1. A holding device, comprising:
a spindle;
a plurality of aligned adapting members mounted on the spindle; and
a plurality of holders each movably coupled with a corresponding adapting member such that the distance between each holder and the spindle is adjustable.

2. The holding device of claim 1, wherein each adapting member comprises a plurality of cylinders, the cylinders radially extending from the spindle.

3. The holding device of claim 1, wherein each adapting member comprises a sleeve and a plurality of cylinders radially extending from the sleeve, and the spindle extends through the sleeve.

4. The holding device of claim 2, wherein each holder is threadedly engaged with a corresponding cylinder.

5. The holding device of claim 2, wherein each holder is telescopically coupled to the corresponding cylinder.

6. The holding device of claim 5, further comprising a plurality of positioning members, wherein each cylinder defines an inner hole receiving the corresponding holder, and a slot communicating with the inner hole, each positioning member extending through the respective slot to secure the corresponding holder in the inner hole of the corresponding cylinder.

7. The holding device of claim 6, wherein a plurality of positioning recesses is defined in each holder, and each positioning member is selectively engagable in one of the positioning recess positioning recesses.

8. The holding device of claim 1, wherein each holder comprises a rod portion movably coupling with the adapting member and a plate portion for holding workpieces, the plate portion perpendicularly extending from the plate portion.

9. The holding device of claim 3, wherein the sleeve is movable along the spindle.

10. The holding device of claim 3, wherein the cylinders of each adapting member are equidistantly and equiangularly spaced from each other.

11. A sputtering apparatus, comprising:
a target;
a plurality of substrates;
a holding device comprising:
a spindle rotatable about a central axis thereof, the spindle being substantially parallel to the target;
a plurality of aligned adapting members mounted on the spindle; and
a plurality of holders securing the respective substrates thereto, each holder movably coupled with a corresponding adapting member such that the distance between each substrate and the target is adjustable.

12. The holding device of claim 11, wherein each adapting member comprises a plurality of cylinders, the cylinders radially extending from the spindle.

13. The holding device of claim 11, wherein each adapting member comprises a sleeve and a plurality of cylinders radially extending from the sleeve, and the spindle extends through the sleeve.

14. The holding device of claim 12, wherein each holder is threadedly engaged with a corresponding cylinder.

15. The holding device of claim 12, wherein each holder is telescopically coupled to the corresponding cylinder.

16. The holding device of claim 15, further comprising a plurality of positioning members, wherein each cylinder defines an inner hole receiving the corresponding holder, and a slot communicating with the inner hole, each positioning member extending through the respective slot to secure the corresponding holder in the inner hole of the corresponding cylinder.

17. The holding device of claim 16, wherein a plurality of positioning recesses is defined in each holder, and each positioning member is selectively engagable in one of the positioning recess positioning recesses.

18. The holding device of claim 11, wherein each holder comprises a rod portion movably coupling with the adapting member and a plate portion for holding workpieces, the plate portion perpendicularly extending from the plate portion.

19. The holding device of claim 13, wherein the sleeve is movable along the spindle.

20. The holding device of claim 13, wherein the cylinders of each adapting member are equidistantly and equiangularly spaced from each other.
